(19) United States
(12) Patent Application Publication
(10) Pub. No.: US 2026/0153549 A1
(43) Pub. Date: Jun. 4, 2026

(54) PROBE STATION FOR TESTING ANTENNA AND ITS OPERATION METHOD

(71) Applicant: SEOUL NATIONAL UNIVERSITY R&DB FOUNDATION, Seoul (KR)

(72) Inventors: Jungsuek OH, Seoul (KR); Dongyeon SEO, Seoul (KR)

(21) Appl. No.: 19/191,479

(22) Filed: Apr. 28, 2025

(30) Foreign Application Priority Data
Dec. 2, 2024 (KR) 10-2024-0176672

(51) Int. Cl. G01R 29/08

(52) U.S. Cl. CPC G01R 29/0878; G01R 29/0871

(57) ABSTRACT

A probe station according to an embodiment includes: a chuck configured to fix a test target antenna; a turn table configured to support the chuck from below and rotate around a vertical axis; a probe configured to apply a test signal to the test target antenna; a receiver antenna configured to detect an antenna signal emitted from the test target antenna when the test signal is applied; a measurement device configured to store the signal detected by the receiver antenna; a base on which the turn table and the receiver antenna are disposed; and a controller configured to control operation states of the probe and the receiver antenna. Herein, the chuck includes a support surface to which the test target antenna is fixed, and the support surface is aligned parallel to the vertical axis.

### CROSS-REFERENCE TO RELATED APPLICATION

This application claims the benefit under 35 USC 119(a) of Korean Patent Applications No. 10-2024-0176672 filed on Dec. 2, 2024 in the Korean Intellectual Property Office, the entire disclosures of which are incorporated herein by reference for all purposes.

### TECHNICAL FIELD

The present disclosure relates to a probe station for testing an antenna and its operation method.

### BACKGROUND

Recently, with the rapid advancement of wireless communication technology, there is an increasing demand for antennas that operate across various frequency bands. These antennas are essential components of communication devices and significantly affect transmission and reception performance. Accurate and precise testing is critical to evaluating and optimizing antenna performance.

In this regard, Korean Patent Laid-open Publication No. 10-2024-0043705 (entitled “Semiconductor device and method for improved antenna testing”) discloses a semiconductor device that tests an antenna by placing an antenna-in-package (AiP) module under a test antenna.

However, according to conventional technologies, a receiver antenna needs to be placed at a far-field distance away from a chuck in a vertical direction of a measurement antenna. Thus, as the size of the measurement antenna increases, the far-field distance increases, which causes spatial limitations in positioning the receiver antenna.

Further, when measuring a radiation pattern, the receiver antenna rotates around the measurement antenna once. Since the receiver antenna moves in a wide range, a cable connected between Vector Network Analyzers (VNAs) move significantly, which may degrade calibration of the antenna and lead to inaccurate measurement results.

Furthermore, an additional external module is used to perform antenna measurements in the D-band or G-band. However, it is impossible to use the external module without revamping the measurement equipment.

### SUMMARY

In view of the foregoing, the present disclosure is conceived to provide a probe station and its operation method. A chuck of the probe station is vertically fixed and power is supplied by probing an antenna with a probe on a side surface, and, thus, a radiation surface of the antenna can be positioned to face the side surface. Therefore, it is possible to place a receiver antenna farther than a far-field distance to suit different measurement antennas.

The problems to be solved by the present disclosure are not limited to the above-described problems. There may be other problems to be solved by the present disclosure.

An aspect of the present disclosure provides a probe station for testing an antenna, including: a chuck configured to fix a test target antenna; a turn table configured to support the chuck from below and rotate around a vertical axis; a probe configured to apply a test signal to the test target antenna; a receiver antenna configured to detect an antenna signal emitted from the test target antenna when the test signal is applied; a measurement device configured to store the signal detected by the receiver antenna; a base on which the turn table and the receiver antenna are disposed; and a controller configured to control operation states of the probe and the receiver antenna. Herein, the chuck includes a support surface to which the test target antenna is fixed, and the support surface is aligned parallel to the vertical axis.

Another aspect of the present disclosure provides an operation method of the probe station, including: a process (a) of applying the test signal to the test target antenna through the probe; and a process (b) of storing, in the measurement device, the signal detected by the receiver antenna.

According to an embodiment of the present disclosure, it is possible to provide a probe station whose chuck is vertically fixed and in which power is supplied by probing an antenna with a probe on a side surface, and, thus, a radiation surface of the antenna can be positioned to face the side surface. Therefore, it is possible to place a receiver antenna farther than a far-field distance to suit different measurement antennas.

Also, according to an embodiment of the present disclosure, a structure configured to minimize movements of a cable connected to the probe when the vertically fixed chuck rotates 360° is used. Therefore, it is possible to continuously maintain calibration.

Further, according to an embodiment of the present disclosure, software driving the probe station has a function to automatically measure and store radiation pattern data when a contact position of the probe is set. Therefore, it is possible to readily measure radiation patterns.

Furthermore, according to an embodiment of the present disclosure, the probe station can measure not only radiation patterns of antennas, but also radiation patterns of lens-coupled antennas, IC performance, and characteristics of system modules, such as Antenna-on-Package (AoP).

### BRIEF DESCRIPTION OF THE DRAWINGS

In the detailed description that follows, embodiments are described as illustrations only since various changes and modifications will become apparent to a person with ordinary skill in the art from the following detailed description. The use of the same reference numbers in different FIG. s indicates similar or identical items.

FIG. 1 is a perspective view of a probe station according to an embodiment of the present disclosure.

FIG. 2 is a perspective view of a chuck according to an embodiment of the present disclosure.

FIG. 3 is a perspective view of an antenna fixing jig according to an embodiment of the present disclosure.

FIG. 4 is a perspective view of the antenna fixing jig according to another embodiment of the present disclosure.

FIG. 5 is a diagram illustrating a chuck driver according to an embodiment of the present disclosure.

FIG. 6 is an enlarged view of a portion A of FIG. 1.

FIG. 7 is a partially enlarged view of the probe station according to an embodiment of the present disclosure.

FIG. 8 and FIG. 9 are diagrams illustrating examples of a test target antenna depending on the radiation direction according to an embodiment of the present disclosure.

FIG. 10 and FIG. 11 are diagrams illustrating a contact substrate according to an embodiment of the present disclosure.

FIG. 12 is a diagram illustrating a calibration substrate according to an embodiment of the present disclosure.

FIG. 13 is a perspective view of a probe station according to an additional embodiment of the present disclosure.

FIG. 14 is a flowchart showing an operation method of the probe station according to an embodiment of the present disclosure.

### DETAILED DESCRIPTION

Hereafter, embodiments will be described in detail with reference to the accompanying drawings so that the present disclosure may be readily implemented by a person with ordinary skill in the art. However, it is to be noted that the present disclosure is not limited to the embodiments but can be embodied in various other ways. In the drawings, parts irrelevant to the description are omitted for the simplicity of explanation, and like reference numerals denote like parts throughout the whole document.

Throughout this document, the term “connected to” may be used to designate a connection or coupling of one element to another element and includes both an element being “directly connected to” another element and an element being “electronically connected to” another element via another element. Further, throughout the whole document, the term “comprises or includes” and/or “comprising or including” used in the document means that one or more other components, steps, operation and/or existence or addition of elements are not excluded in addition to the described components, steps, operation and/or elements unless context dictates otherwise.

Throughout the whole document, the term “unit” includes a unit implemented by hardware or software and a unit implemented by both of them. One unit may be implemented by two or more pieces of hardware, and two or more units may be implemented by one piece of hardware. However, the “unit” is not limited to the software or the hardware and may be stored in an addressable storage medium or may be configured to implement one or more processors. Accordingly, the “unit” may include, for example, software, object-oriented software, classes, tasks, processes, functions, attributes, procedures, sub-routines, segments of program codes, drivers, firmware, micro codes, circuits, data, database, data structures, tables, arrays, variables and the like. The components and functions provided by the “unit” may be either combined into a smaller number of components and “units” or divided into a larger number of components and “units”. Moreover, the components and “units” may be implemented to reproduce one or more CPUs within a device or a secure multimedia card.

The present disclosure relates to a probe station for testing an antenna and its operation method.

Hereafter, embodiments of the present disclosure will be described in detail with reference to the accompanying drawings.

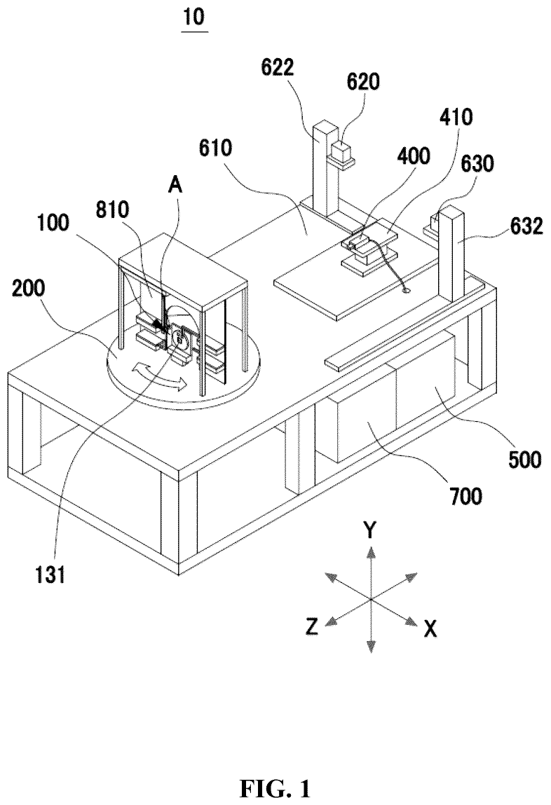

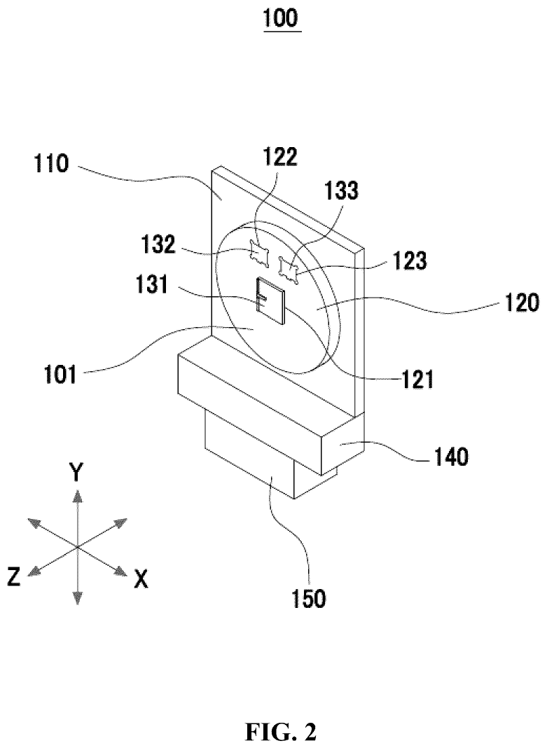

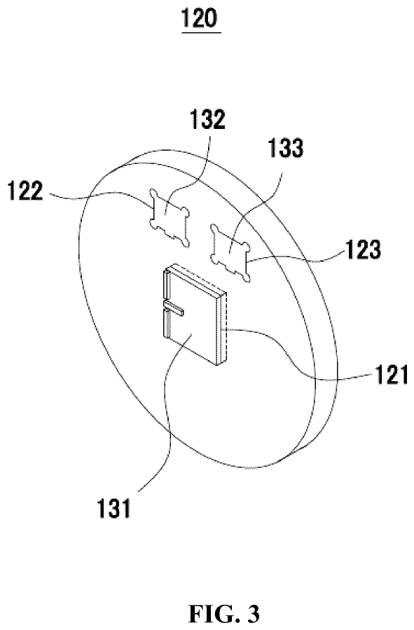

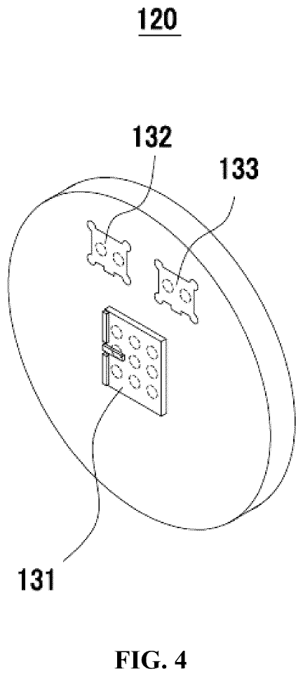

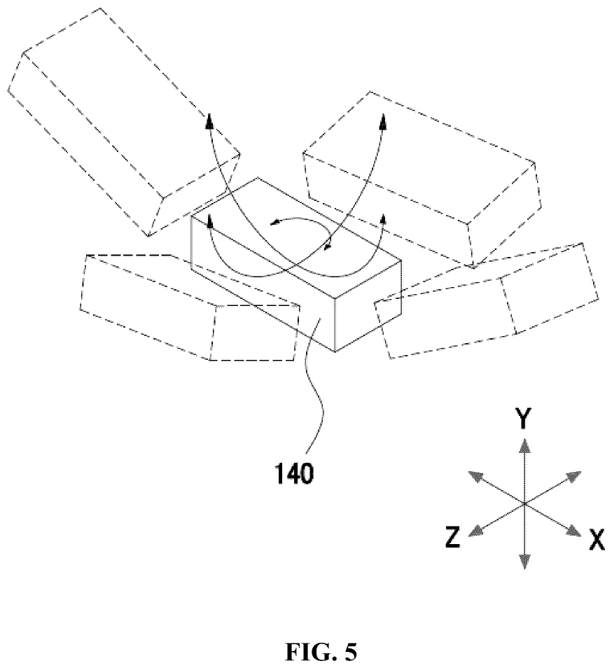

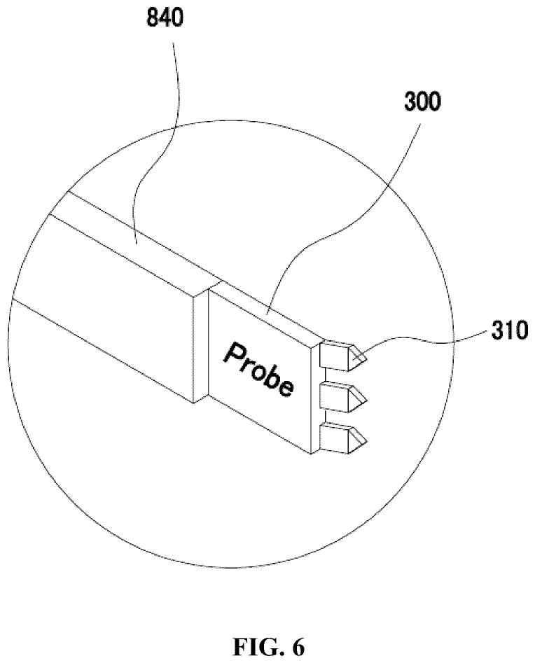

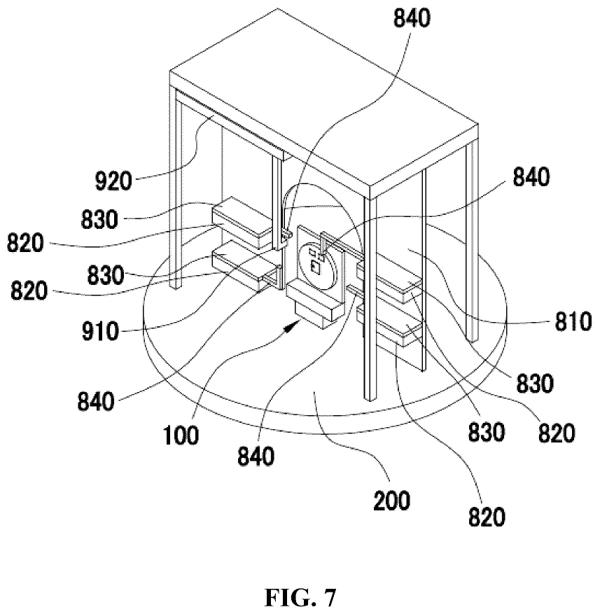

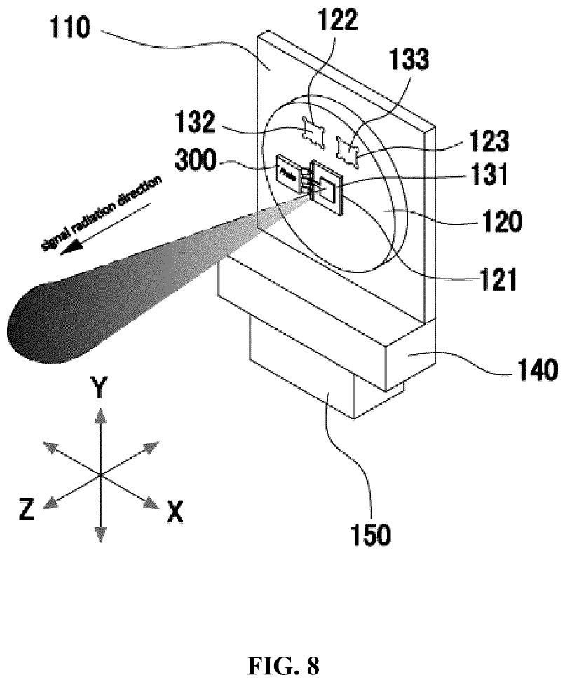

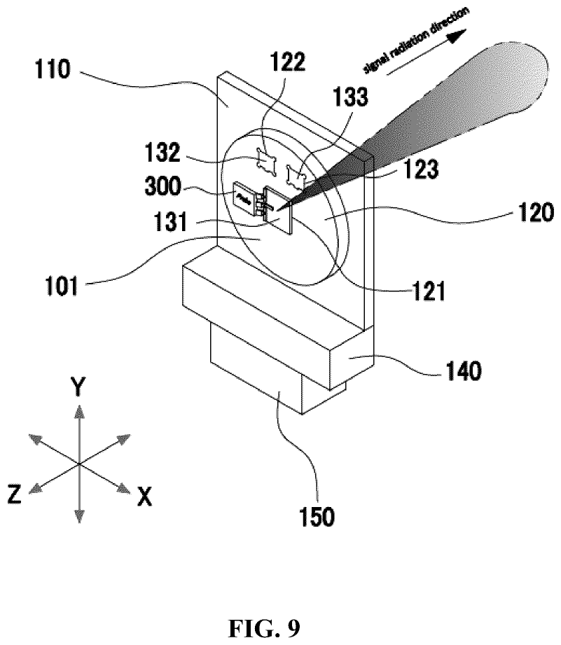

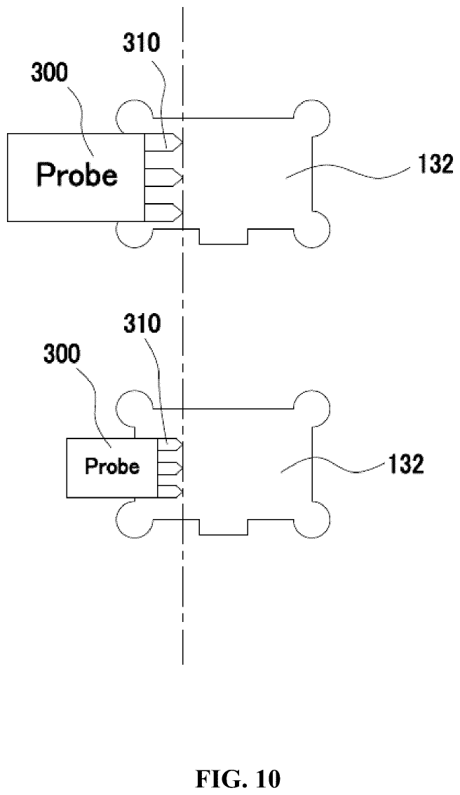

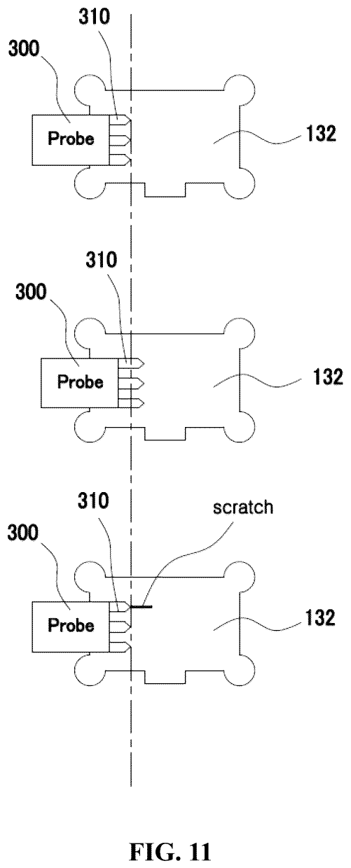

FIG. 1 is a perspective view of a probe station according to an embodiment of the present disclosure, FIG. 2 is a perspective view of a chuck according to an embodiment of the present disclosure, FIG. 3 is a perspective view of an antenna fixing jig according to an embodiment of the present disclosure, FIG. 4 is a perspective view of the antenna fixing jig according to another embodiment of the present disclosure, FIG. 5 is a diagram illustrating a chuck driver according to an embodiment of the present disclosure, FIG. 6 is an enlarged view of a portion A of FIG. 1, FIG. 7 is a partially enlarged view of the probe station according to an embodiment of the present disclosure, FIG. 8 and FIG. 9 are diagrams illustrating examples of a test target antenna depending on the radiation direction according to an embodiment of the present disclosure, and FIG. 10 and FIG. 11 are diagrams illustrating a contact substrate according to an embodiment of the present disclosure.

Referring to FIG. 1, a probe station 10 includes a chuck 100, a turn table 200, a probe 300, a receiver antenna 400, a measurement device 500, a base 610, and a controller 700.

Referring to FIG. 2, a test target antenna 131 is fixed to the chuck 100. Also, the chuck 100 includes a support surface 101 to which the test target antenna 131 is fixed, and the support surface 101 is aligned parallel to a vertical axis.

The chuck 100 may include a chuck body 110 formed into a flat shape and aligned parallel to the vertical axis, and an antenna fixing jig 120 detachably coupled to the chuck body 110. Herein, the antenna fixing jig 120 may be formed of Rohacell, ROHACRYL, acrylic, plastic, or Styrofoam, but is not limited thereto. The antenna fixing jig 120 may be formed of various other materials. For reference, ROHACRYL is a product of Evonik, the manufacturer of Rohacell, and has a dielectric constant (dielectric constant: 1) almost identical to that of Rohacell.

For example, as shown in FIG. 2, the chuck body 110 is formed into a plate shape, and has a hollow at a central portion thereof. The antenna fixing jig 120 can be inserted into the hollow and fixed therein.

Referring to FIG. 3, the antenna fixing jig 120 may include an antenna mounting groove 121, a contact substrate mounting groove 122, and a calibration substrate mounting groove 123.

The antenna mounting groove 121 may be formed to mount the test target antenna 131 thereon. For example, the antenna mounting groove 121 may be formed by denting or puncturing a central portion of the antenna fixing jig 120 into a rectangular shape, but the shape of the antenna mounting groove 121 is not limited thereto. Also, the test target antenna 131 may be fixed by being inserted into the antenna mounting groove 121.

The contact substrate mounting groove 122 may be formed to mount a contact substrate 132 thereon. The contact substrate 132 is provided to measure a flatness that indicates the degree of proximity or contact between the contact substrate 132 and a plurality of tips 310 of the probe 300 at a constant distance from the test target antenna 131. Also, the contact substrate mounting groove 122 may be dented into a shape, which corresponds to the shape of the contact substrate 132, in a surface where the probe 300 is located in order to allow the probe 300 to contact with the contact substrate 132. Details of the contact substrate 132 will be described below.

The calibration substrate mounting groove 123 may be formed to mount a calibration substrate 133 thereon. The calibration substrate 133 is provided to perform calibration to correct effects caused by the probe 300. Also, the calibration substrate mounting groove 123 may be dented into a shape, which corresponds to the shape of the calibration substrate 133, in the surface where the probe 300 is located in order to allow the probe 300 to contact with the calibration substrate 133. Details of the calibration substrate 133 will be described below.

Referring to FIG. 4, in another embodiment, the antenna fixing jig 120 may fix the test target antenna 131, the contact substrate 132 for flatness measurement, and the calibration substrate 133 by vacuum suction. For example, as shown in FIG. 4, the antenna fixing jig 120 includes a plurality of holes where the test target antenna 131, the contact substrate 132 for flatness measurement, and the calibration substrate 133 are sucked. A suction force is generated in the plurality of holes to fix test target antenna 131, the contact substrate 132 for flatness measurement, and the calibration substrate 133 by vacuum suction.

Referring back to FIG. 2, the chuck 100 may further include a chuck support 140 configured to support the chuck body 110 from below, and a chuck driver 150 disposed between the chuck support 140 and the turn table 200 and configured to adjust a position of the chuck support 140 in an X-axis, Y-axis or Z-axis direction. Further, referring to FIG. 5, the chuck driver 150 may perform a function of tilting the chuck support 140 in both directions along the X-axis around the Z-axis, tilting the chuck support 140 in both directions along the Z-axis around the X-axis, or rotating the chuck support 140 360° around the vertical axis. For example, the chuck driver 150 may include a plurality of motors, rails, and other components that enable the movement and tilting of the chuck support 140 along the X-axis, the Y-axis, and the Z-axis. Since the movement and tilting along the X-axis, the Y-axis, and the Z-axis is a common configuration, a detailed description thereof will be omitted.

Referring to FIG. 7, the turn table 200 supports the chuck 100 from below and rotates around the vertical axis. Further, the chuck 100, a stand 810, an additional device support 830, a probe arm 840, the probe 300, and the like are mounted on the turn table 200, and the turn table 200 can rotate along a radiation direction of the test target antenna 131 fixed to the chuck 100. In other words, if the test target antenna 131 emits a signal to a surface with which the probe 300 is brought into contact (see FIG. 8), the turn table 200 may rotate the surface with which the probe 300 is brought into contact to face in a direction of the receiver antenna 400. Also, if the test target antenna 131 emits a signal in a direction opposite to the surface with which the probe 300 is brought into contact (see FIG. 9), the probe 300 the turn table 200 may rotate the other surface to face in the direction of the receiver antenna 400.

Also, according to the present disclosure, the turn table 200 has a hole punctured at its to allow a cable connected to the probe 300 to pass therethrough. Therefore, even when the turn table 200 is rotated, it is possible to minimize movements of the cable and continuously maintain calibration.

Referring to FIG. 6, the probe 300 applies a test signal to the test target antenna 131. Further, the probe 300 or the probe tips 310 may be formed to be bent at a predetermined angle toward the test target antenna 131. For example, the probe 300 may be a Radio Frequency (RF) probe or a Direct Current (DC) probe.

For example, the probe 300 includes three probe tips 310. The thee probe tips 310 may include two grounding tips configured to be in contact with a grounding pad, and a signal probe tip configured to be in contact with a signal pad and located between the grounding probe tips. Herein, the probe station 10 may be a device to test a Ground Signal Ground (GSG) test pattern which is one of test patterns of the antenna 131.

Referring to FIG. 7, the probe station 10 may further include a microscope 910 located toward the test target antenna 131, and a linear rail 920 fixed to one side of the stand 810 and configured to adjust a position of the microscope 910. Herein, the linear rail 920 may be provided to adjust a position of the microscope 910 in the X-axis direction or the Z-axis direction.

Further, the probe station 10 can adjust a flatness of the probe 300 by imaging the probe 300 with the microscope 910.

The contact substrate 132 is provided to measure the flatness that indicates the degree of proximity or contact between the contact substrate 132 and the plurality of tips 310 of the probe 300 at a constant distance from the test target antenna 131. The microscope 910 is used to image the contact between the plurality of tips 310 of the probe 300 and the contact substrate 132, and the flatness of the probe 300 can be adjusted based on the image information.

Referring to FIG. 10, as the probe 300 approaches the contact substrate 132, the probe 300 observed through the microscope 910 may appear increasingly smaller. Then, referring to FIG. 11, the probe 300 comes into contact with the contact substrate 132, and as it is lowered in the Z-axis direction, the probe 300 is pushed to one side. Thus, scratches may occur on the contact substrate 132 by the probe tips 310. In this case, if the probe 300 is aligned flat in a normal state, when all the three probe tips 310 are each in uniform contact with the contact substrate 132, each scratch will have the same pattern. However, if the probe 300 is tilted to one side, scratches may occur by one of the three probe tips 310, which results in different scratch patterns. As such, flatness conditions of the probe 300 can be determined by analyzing scratch patterns. By analyzing scratch patterns imaged with the microscope 910 as the probe 300 is raised in the Z-axis direction, the flatness of the probe 300 is measured and the flatness conditions of the probe 300 are determined. Then, the flatness of the probe 300 can be adjusted by using a probe driver 820.

For example, as shown in FIG. 11, when a scratch occurs only by an uppermost one of the probe tips 310 of the probe 300, the probe 300 is tilted toward the uppermost probe tip 310. Thus, the flatness of the probe 300 can be adjusted by tilting the probe 300 at a predetermined angle around the X-axis.

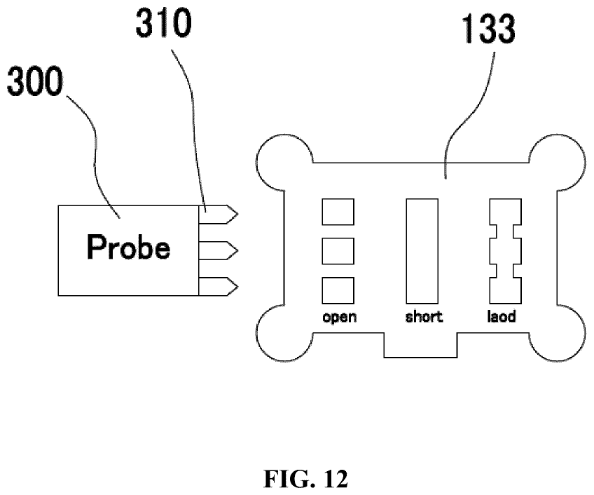

Referring to FIG. 12, the calibration substrate 133 is provided to perform calibration to correct the effects caused by the probe 300. For example, the calibration substrate 133 may receive a signal transmitted from the probe 300, measure an error, such as a signal delay, and correct the error. For example, calibration may be performed by calculating the differences between values measured when the plurality of tips 310 of the probe 300 is in contact with open, short, and load ports of the calibration substrate 133 and a basic response value. Through this process, a phase shift caused by the length of the cable can be corrected and effects of surrounding noise can be counteracted.

Referring back to FIG. 1, as a test signal is applied, the receiver antenna 400 detects an antenna signal emitted from the test target antenna 131. The receiver antenna 400 may be wiredly or wirelessly connected to the measurement device 500 to transmit the detected antenna signal. Also, the probe station 10 may further include a receiver antenna support 410 which is located on the base 610 and on which the receiver antenna 400 is mounted. A position of the receiver antenna support 410 can be adjusted in the X-axis, Y-axis or Z-axis direction on the base 610. In other words, distances between different measurement antennas 131 and the receiver antenna 400 to suit the measurement antennas 131 can be adjusted to place the receiver antenna support 410 farther than a far-field distance.

The measurement device 500 stores the signal detected by the receiver antenna 400. In other words, the measurement device 500 may extract a radiation pattern of the test target antenna 131 from the signal detected by the receiver antenna 400 and store it.

The turn table 200 and the receiver antenna 400 are located on the base 610. In other words, the turn table 200 may be formed into a plate shape on the base 610 and detachably coupled onto the base 610, and the receiver antenna 400 may be spaced apart by a predetermined distance from the turn table 200 on the base 610.

The controller 700 controls operation states of the turn table 200, the probe 300, and the receiver antenna 400. Specifically, the controller 700 controls the probe 300 to apply a test signal for each rotation angle while rotating the turn table 200 at a predetermined rotation angle and allows a signal detected by the receiver antenna 400 for each rotation angle to be stored in the measurement device 500. Details thereof will be described below.

Referring back to FIG. 7, the probe station 10 may further include the stand 810 and the additional device support 830.

The stand 810 may be fixed to the turn table 200 while surrounding the chuck 100. For example, the stand 810 may be formed into a plate shape and fixed to an upper surface of the turn table 200, and may provide a space for the chuck 100 at its lower part.

The additional device support 830 may be fixed to one side of the stand 810, equipped with the probe driver 820 fixed to its one side, and allows additional devices to be mounted thereon. The probe driver 820 serves to adjust a position of the probe 300. Herein, the additional devices may include a frequency expander configured to adjust a frequency of the test signal applied to the probe 300 or a power meter configured to measure a power of a radiation signal output from the test target antenna 131.

The additional device support 830 may perform a function of adjusting a position in the X-axis, Y-axis or Z-axis direction, tilting in both directions along the Y-axis around the X-axis, tilting in both directions along the X-axis around the Y-axis, or tilting in both directions along the Y-axis around the Z-axis. For example, the additional device support 830 may be fixed onto the probe driver 820, and its movements may be controlled as the probe driver 820 is moved or tilted.

The probe driver 820 may adjust a distance or contact state between the probe 300 and the test target antenna 131 along the Z-axis.

The controller 700 controls the probe driver 820 and the additional device support 830 to adjust the flatness that indicates the degree of proximity or contact of the plurality of tips 310 of the probe 300 at a constant distance from the test target antenna 131. In other words, the controller 700 controls the probe driver 820 to adjust a distance between the tip 310 of the probe 300 and the test target antenna 131 along the Z-axis, and controls the tilting of the additional device support 830 to adjust a flatness of the plurality of tips 310 of the probe 300 and the test target antenna 131.

Also, the controller 700 controls the receiver antenna support 410 to adjust a distance between the test target antenna 131 and the receiver antenna 400 depending on a frequency band of an antenna signal emitted from the test target antenna 131. For example, a distance between the test target antenna 131 and the receiver antenna 400 when the frequency band of the antenna signal is in the D-band (110 GHz to 170 GHz) according to the IEEE standard may be set to be longer than a distance between the test target antenna 131 and the receiver antenna 400 when the frequency band of the antenna signal is in the G-band (110 GHz to 300 GHz) according to the IEEE standard.

Referring back to FIG. 1, the probe station 10 may further include a vertical laser leveler 620 and a horizontal laser leveler 630 located on the base 610 and configured to detect an alignment state of the receiver antenna 400. The probe station 10 may align the test target antenna 131 and the receiver antenna 400 by checking laser beams radiated from the vertical laser leveler 620 and the horizontal laser leveler 630.

The probe station 10 may also include a vertical leveler support 622 on which the vertical laser leveler 620 is mounted and performs the movement in the X-axis direction, the movement in the Y-axis direction, the tilting in both directions along the Y-axis around the X-axis, the tilting in both direction along the Y-axis direction around the Z-axis, and the rotation around the Y-axis, and a horizontal leveler support 632 on which the horizontal laser leveler 630 is mounted and performs the movement in the Z-axis direction, the movement in the Y-axis direction, the tilting in both directions along the Y-axis around the X-axis, the tilting in both directions along the Y-axis around the Z-axis, and the rotation around the Y-axis.

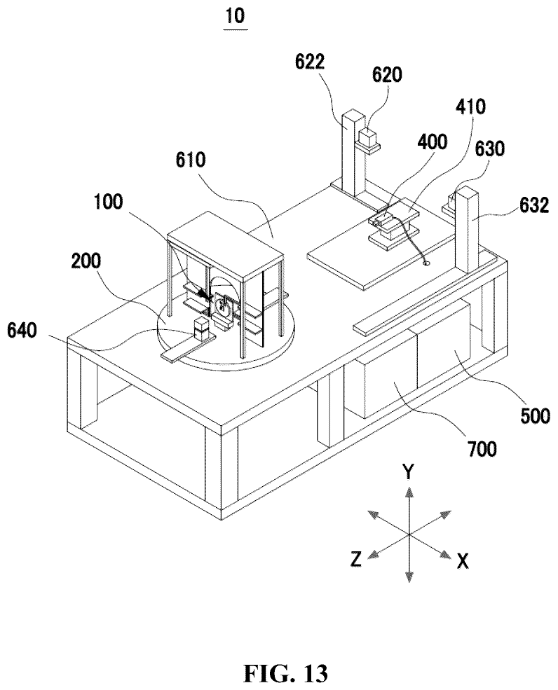

Referring to FIG. 13, the probe station 10 may further include a shield support 640 on which a shield is mounted. The shield is provided for shielding test of the antenna signal emitted from the test target antenna 131. Also, the shield support 640 is located at each of the front and rear of the chuck 100, and may be selectively used depending on the radiation direction of the test target antenna 131.

Further, a position of the shield support 640 can be adjusted in the X-axis, Y-axis or Z-axis direction on the base 610. Furthermore, the shield support 640 may tilt in both directions along the Y-axis around the X-axis, tilt in both directions along the X-axis around the Y-axis, or tilt in both directions along the Y-axis around the Z-axis. Also, the controller 700 can control the shield support 640 or the turn table 200 to place the shield support 640 between the test target antenna 131 and the receiver antenna 400 along the Z-axis direction. Herein, the shield may be an AUT case, a housing, a lens antenna, a spatially coupled antenna, etc. Therefore, the probe station 10 can measure a radiation pattern of an antenna combined with the case, the housing, or the lens antenna as well as a radiation pattern of the antenna 131. Further, the probe station 10 can measure Integrated Circuit (IC) performance and characteristics of system modules, such as Antenna-on-Package (AoP).

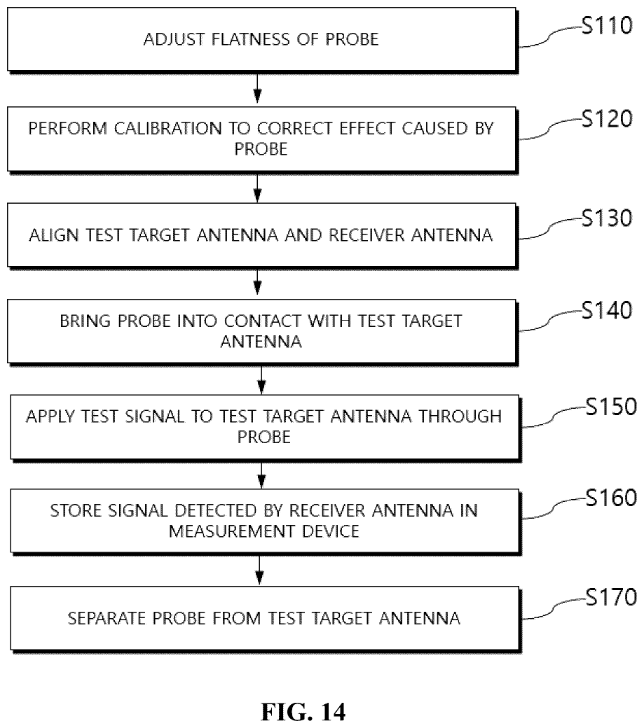

Hereafter, an operation method of the probe station 10 according to an embodiment of the present disclosure will be described with reference to FIG. 14.

In a process S110, a flatness of the probe 300 is adjusted. Specifically, the controller 700 controls the probe driver 820 and the additional device support 830 to adjust the flatness that indicates the degree of proximity or contact between the chuck 100 and the plurality of tips 310 of the probe 300 at a constant distance from the test target antenna 131 in order for the plurality of tips 310 of the probe 300 to approach or make contact with the chuck 100 at a constant distance from the test target antenna 131. Herein, each of the test target antenna 131, the contact substrate 132 for flatness measurement, and the calibration substrate 133 for calibration is fixed onto the chuck 100.

In a process S120, calibration to correct the effects caused by the probe 300 is performed by bring the probe 300 into contact with the calibration substrate 133 at least once. For example, the calibration may be performed to eliminate an error, such as a signal delay caused by various cables or the probe 300. The calibration may be performed by calculating the differences between values measured when the plurality of tips 310 of the probe 300 is in contact with open, short, and load ports of the calibration substrate 133 and a basic response value. Through this process, a phase shift caused by the length of the cable can be corrected and the effects of surrounding noise can be counteracted.

In a process S130, the horizontal laser leveler 630 and the vertical laser leveler 620 are used to align the test target antenna 131 and the receiver antenna 400. In other words, the test target antenna 131 and the receiver antenna 400 may be aligned by checking laser beams radiated from the vertical laser leveler 620 and the horizontal laser leveler 630 and specifically by checking whether a vertical laser beam and a horizontal laser beam intersect in the test target antenna 131 and the receiver antenna 400.

In a process S140, the probe 300 is brought into contact with the test target antenna 131.

In a process S150, a test signal is applied to the test target antenna 131 through the probe 300.

In a process S160, a signal detected by the receiver antenna 400 is stored in the measurement device 500.

In a process S170, the probe 300 is separated from the test target antenna 131.

Also, the controller 700 performs the processes S140, S150, S160 and S170 repeatedly while rotating the turn table 200 at a predetermined rotation angle and allows a signal detected by the receiver antenna 400 for each rotation angle to be stored in the measurement device 500. In other words, the controller 700 can measure a radiation pattern of the test target antenna 131 by rotating the turn table 200 at a start angle of the test target antenna 131, performing a test, rotating the turn table 200 by a predetermined angle, performing the test again, and repeating the processes until the angle reaches an end angle.

The embodiment of the present disclosure can be embodied in a non-transitory storage medium including instruction codes executable by a computer such as a program module executed by the computer. A computer-readable medium can be any usable medium which can be accessed by the computer and includes all volatile/non-volatile and removable/non-removable media. Further, the computer-readable medium may include all computer storage media. The computer storage media include all volatile/non-volatile and removable/non-removable media embodied by a certain method or technology for storing information such as computer-readable instruction code, a data structure, a program module or other data.

The method and system of the present disclosure have been explained in relation to a specific embodiment, but their components or a part or all of their operations can be embodied by using a computer system having general-purpose hardware architecture.

The above description of the present disclosure is provided for the purpose of illustration, and it would be understood by a person with ordinary skill in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

### EXPLANATION OF CODES

10: Probe station
100: Chuck
101: Support surface
110: Chuck body
120: Antenna fixing jig
121: Antenna mounting groove
122: Contact substrate mounting groove
123: Calibration substrate mounting groove
131: Antenna
132: Contact substrate
133: Calibration substrate
140: Chuck support
150: Chuck driver
200: Turntable
300: Probe
310: Probe tip
400: Receiver antenna
410: Receiver antenna support
500: Measurement device
610: Base
620: Vertical laser leveler
622: Vertical leveler support
630: Horizontal laser leveler
632: Horizontal leveler support
640: Shield support
700: Controller
810: Stand
820: Probe driver
830: Additional device support
840: Probe arm
910: Microscope
920: Linear rail

What is claimed is:

1. A probe station for testing an antenna, comprising:
a chuck configured to fix a test target antenna;
a turn table configured to support the chuck from below and rotate around a vertical axis;
a probe configured to apply a test signal to the test target antenna;
a receiver antenna configured to detect an antenna signal emitted from the test target antenna when the test signal is applied;
a measurement device configured to store the signal detected by the receiver antenna;
a base on which the turn table and the receiver antenna are disposed; and
a controller configured to control operation states of the probe and the receiver antenna,
wherein the chuck includes a support surface to which the test target antenna is fixed, and the support surface is aligned parallel to the vertical axis.

2. The probe station of claim 1, wherein the turn table is rotatable 360°.

3. The probe station of claim 1,
wherein the test target antenna on the chuck radiates a signal in a contact direction of the probe or in a direction opposite to the contact direction of the probe.

4. The probe station of claim 1,
wherein the controller controls the probe to apply the test signal for each rotation angle while rotating the turn table at a predetermined rotation angle and allows the signal detected by the receiver antenna for each rotation angle to be stored in the measurement device.

5. The probe station of claim 1, wherein the chuck includes:
a chuck body formed into a flat shape and aligned parallel to the vertical axis; and
an antenna fixing jig detachably coupled to the chuck body.

6. The probe station of claim 5,
wherein the antenna fixing jig is formed of Rohacell, ROHACRYL, acrylic, plastic, or Styrofoam.

7. The probe station of claim 5,
wherein the antenna fixing jig includes:
an antenna mounting groove formed to mount the test target antenna thereon;
a contact substrate mounting groove formed to mount a contact substrate thereon, the contact substrate provided to measure a flatness that indicates the degree of proximity or contact between the contact substrate and a plurality of tips of the probe at a constant distance from the test target antenna; and
a calibration substrate mounting groove formed to mount a calibration substrate thereon, the calibration substrate provided to perform calibration to correct effects caused by the probe.

8. The probe station of claim 5,
wherein the antenna fixing jig fixes the test target antenna, a contact substrate for flatness measurement, and a calibration substrate by vacuum suction,
the contact substrate is provided to measure a flatness that indicates the degree of proximity or contact between the contact substrate and a plurality of tips of the probe at a constant distance from the test target antenna, and
the calibration substrate is provided to perform calibration to correct effects caused by the probe.

9. The probe station of claim 5,
wherein the chuck includes:
a chuck support configured to support the chuck body from below; and
a chuck driver disposed between the chuck support and the turn table and configured to adjust a position of the chuck support in an X-axis, Y-axis or Z-axis direction.

10. The probe station of claim 9,
wherein the chuck driver performs a function of tilting the chuck support in both directions along the X-axis around the Z-axis, tilting the chuck support in both directions along the Z-axis around the X-axis, or rotating the chuck support 360° around the vertical axis.

11. The probe station of claim 1, further comprising:
a stand fixed to the turn table while surrounding the chuck;
an additional device support fixed to one side of the stand, equipped with a probe driver fixed to its one side, and allows additional devices to be mounted thereon, and the probe driver serving to adjust a position of the probe; and
a probe arm which is provided on one side of the probe driver and to which the probe is fixed.

12. The probe station of claim 11,
wherein the probe driver adjusts a distance or contact state between the probe and the test target antenna along an Z-axis.

13. The probe station of claim 11,
wherein the additional devices include a frequency expander configured to adjust a frequency of the test signal applied to the probe or a power meter configured to measure a power of a radiation signal output from the test target antenna.

14. The probe station of claim 11,
wherein the additional device support performs a function of adjusting a position in an X-axis, Y-axis or Z-axis direction, tilting in both directions along the Y-axis around the X-axis, tilting in both directions along the X-axis around the Y-axis, or tilting in both directions along the Y-axis around the Z-axis.

15. The probe station of claim 14,
wherein the controller controls the probe driver and the additional device support to adjust a flatness that indicates the degree of proximity or contact of a plurality of tips of the probe at a constant distance from the test target antenna,
the controller controls the probe driver to adjust a distance between the tip of the probe and the test target antenna along the Z-axis, and
the controller controls the tilting of the additional device support to adjust a flatness of the plurality of tips of the probe and the test target antenna.

16. The probe station of claim 11, further comprising:
a microscope located toward the test target antenna; and
a linear rail fixed to one side of the stand and configured to adjust a position of the microscope,
wherein the linear rail is provided to adjust a position of the microscope 910 in an X-axis direction or a Z-axis direction.

17. The probe station of claim 1, further comprising:
a receiver antenna support which is located on the base and on which the receiver antenna is mounted,
wherein a position of the receiver antenna support is adjusted in an X-axis, Y-axis or Z-axis direction on the base.

18. The probe station of claim 17,
wherein the controller controls the receiver antenna support to adjust a distance between the test target antenna and the receiver antenna depending on a frequency band of the antenna signal emitted from the test target antenna.

19. The probe station of claim 17, further comprising:
a vertical laser leveler and a horizontal laser leveler located on the base and configured to detect an alignment state of the receiver antenna.

20. The probe station of claim 1, further comprising:
a shield support on which a shield is mounted, the shield provided for shielding test of the antenna signal emitted from the test target antenna,
wherein a position of the shield support is adjusted in an X-axis, Y-axis or Z-axis direction on the base or the shield support tilts in both directions along the Y-axis around the X-axis, tilts in both directions along the X-axis around the Y-axis, or tilts in both directions along the Y-axis around the Z-axis.

21. The probe station of claim 20,
wherein the controller controls the shield support or the turn table to place the shield support between the test target antenna and the receiver antenna along the Z-axis direction.

22. The probe station of claim 1,
wherein the extracts a radiation pattern of the test target antenna from the signal detected by the receiver antenna and stores it.

23. An operation method of the probe station of claim 1,
a process (a) of applying the test signal to the test target antenna through the probe; and
a process (b) of storing, in the measurement device, the signal detected by the receiver antenna.

24. The operation method of the probe station of claim 23,
wherein the controller performs the processes (a) and (b) repeatedly while rotating the turn table at a predetermined rotation angle and allows the signal detected by the receiver antenna for each rotation angle to be stored in the measurement device.

25. The operation method of the probe station of claim 23, further comprising:
a process of bringing the probe into contact with the test target antenna before the process (a); and
a process of separating the probe from the test target antenna after the process (b),
wherein the controller performs the process of bringing the probe into contact with the test target antenna, the processes (a) and (b), and the process of separating the probe from the test target antenna repeatedly while rotating the turn table at a predetermined rotation angle and allows the signal detected by the receiver antenna for each rotation angle to be stored in the measurement device.

26. The operation method of the probe station of claim 23, further comprising:
before the process (a),
a process in which the controller controls the probe driver and the additional device support to adjust a flatness that indicates the degree of proximity or contact between the chuck and the plurality of tips of the probe at a constant distance from the test target antenna in order for the plurality of tips of the probe to approach or make contact with the chuck at a constant distance from the test target antenna,
wherein each of the test target antenna, the contact substrate for flatness measurement, and the calibration substrate for calibration is fixed onto the chuck.

27. The operation method of the probe station of claim 26, further comprising:
after the process of adjusting the flatness and before the process (a),
a process of performing calibration to correct effects caused by the probe by bring the probe into contact with the calibration substrate at least once.
